(19) United States
(12) Patent Application Publication
(10) Pub. No.: US 2025/0113577 A1
(43) Pub. Date: Apr. 3, 2025

(54) SEMICONDUCTOR AIRGAP SPACER AND FABRICATION METHODS

(71) Applicant: Applied Materials, Inc., Santa Clara, CA (US)

(72) Inventors: Veeraraghavan S. Basker, Fremont, CA (US); Sai Hooi Yeong, Cupertino, CA (US); Ashish Pal, San Ramon, CA (US); El Mehdi Bazizi, San Jose, CA (US); Benjamin Colombeau, San Jose, CA (US); Balasubramanian Pranatharthiharan, San Jose, CA (US)

(73) Assignee: Applied Materials, Inc., Santa Clara, CA (US)

(21) Appl. No.: 18/893,455

(22) Filed: Sep. 23, 2024

Related U.S. Application Data
(60) Provisional application No. 63/541,739, filed on Sep. 29, 2023.

(51) Int. Cl. H01L 29/66; H01L 21/8238; H01L 27/092; H01L 29/06; H01L 29/423; H01L 29/775; H01L 29/78; H01L 29/786

(52) U.S. Cl. CPC H10D 64/021; H10D 30/014; H10D 30/024; H10D 30/43; H10D 30/6211; H10D 30/6735; H10D 30/6757; H10D 62/121; H10D 64/017; H10D 84/0188; H10D 84/038; H10D 84/853

(57) ABSTRACT

Embodiments of the disclosure advantageously provide semiconductor devices, fin field effect transistors (FinFETs) in particular, and methods of manufacturing such devices having improved effective capacitance (C_{eff}). The FinFETs include a gate structure in which airgaps are provided by recessing a high-k material layer disposed between the gate structure and a spacer layer, thereby reducing the effective dielectric constant in the high-k dielectric layer and improving effective capacitance (C_{eff}) of the device.

### CROSS-REFERENCE TO RELATED APPLICATIONS

This application claims priority to U.S. Provisional Application No. 63/541,739, filed Sep. 29, 2023, the entire disclosures of which are hereby incorporated by reference herein.

### TECHNICAL FIELD

Embodiments of the disclosure generally relate to semiconductor devices and methods of fabrication. More particularly, embodiments of the disclosure are directed to field effect transistors (FETs) in which airgaps are provided by recessing a high-k material within a gate structure, thereby improving effective capacitance (C_{eff}) of the device.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits.

However, as the feature sizes of transistor devices continue to shrink to achieve greater circuit density and higher performance, parasitic capacitance and off-state leakage become a problem. Thus, there is a need to improve transistor device design and fabrication to allow for further reduction in device size while reducing these negative effects.

### SUMMARY

An aspect of the disclosure is directed to a semiconductor device comprising a semiconductor stack disposed on a substrate; a metal gate structure disposed on a top surface of the semiconductor stack, the metal gate structure having a bottom surface, a top surface, and lateral side surfaces; a high-k dielectric layer disposed between the bottom surface of the metal gate structure and the top surface of the semiconductor stack, and on a bottom portion of the lateral side surfaces of the metal gate structure; a spacer layer extending along the lateral side surfaces of the metal gate structure, wherein the spacer layer is separated from the lateral side surfaces of the metal gate structure by (a) the high-k dielectric layer disposed between the spacer layer and metal gate structure on the bottom portion of the lateral side surfaces of the metal gate structure, and (b) an airgap disposed between the spacer layer and metal gate structure above the bottom portion of the lateral side surfaces of the metal gate structure; and a gate cap material disposed on the top surface of the metal gate structure, the gate cap material extending above but not into the airgap. The airgap provides a reduced effective dielectric constant between the lateral side surfaces of the metal gate structure and the spacer layer.

Another aspect of the disclosure is directed to a replacement metal gate structure for a semiconductor device comprising a gate metal fill; at least one work function metal layers surrounding a bottom surface and lateral side surfaces of the gate metal fill; a high-k dielectric layer surrounding a bottom surface and a bottom portion of the lateral side surfaces of the gate metal fill, the at least one work function layer disposed between the high-k dielectric layer and the gate metal fill; a spacer layer extending along the lateral side surfaces of the gate metal fill, the high-k dielectric layer disposed between the spacer layer and the at least one work function layer at the bottom portion of the lateral side surfaces of the gate metal fill, and an airgap disposed between the spacer layer and the at least one work function layer above the high-k dielectric layer, the airgap providing a reduced effective dielectric constant in the high-k dielectric layer and improves an effective capacitance of the semiconductor structure; and a gate cap material disposed between the spacer layer and extending along a top surface of the metal gate fill and above the airgap.

Another aspect of the disclosure is directed to method of forming a semiconductor structure, the method comprising providing a semiconductor stack on a substrate surface with a gate structure on a top surface of the semiconductor stack, a spacer structure extending along outer lateral sides of the gate structure, and a high-k dielectric layer disposed between the spacer structure and the gate structure; selectively removing at least a portion of the high-k dielectric layer to provide an opening between the spacer structure and the gate structure; and depositing a gate cap material on a top surface of the gate structure to block the opening and form an airgap between the spacer structure and the gate structure.

Another aspect of the disclosure is directed to a method of forming an airgap within a semiconductor structure, the method comprising providing a gate structure on a top surface of a semiconductor stack, the gate structure having a bottom surface, a top surface and lateral side surfaces, a spacer structure extending along the outer lateral sides of the gate structure, and a high-k dielectric layer disposed between the spacer structure and the gate structure along the outer lateral sides of the gate structure; selectively removing at least a portion of the high-k dielectric layer between the top surface of the gate structure to a depth along the outer lateral sides of the gate structure to provide an opening between the spacer structure and the gate structure; and depositing a gate cap material extending along the top surface of the gate structure and over the opening to block the opening and form an airgap between the spacer structure and the gate structure, the airgap providing a reduced effective dielectric constant in the high-k dielectric layer and improves an effective capacitance of the semiconductor structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a bi-cross-sectional view of a FinFET device having dummy gate stacks with formed across semiconductor stacks according to one or more embodiments;

FIG. 1B illustrates a side cross sectional view of a dummy gate stack of FIG. 1A;

FIG. 1C illustrates a bi-cross sectional view of the FinFET device of FIG. 1A with replacement metal gate (RMG) stacks formed according to one or more embodiments;

FIG. 1D illustrates a side cross sectional view of a replacement metal gate (RMG) stack of FIG. 1C;

FIG. 1E illustrates a bi-cross sectional view of the FinFET device of FIG. 1C after the replacement metal gate (RMG) stacks have been recessed according to one or more embodiments;

FIG. 1F illustrates a side cross sectional view of a replacement metal gate (RMG) stack of FIG. 1E;

FIG. 1G illustrates a bi-cross sectional view of the FinFET device of FIG. 1E after a high-k gate dielectric layer has been recessed to expose spacers and form gaps between the spacers and outer lateral sides of a replacement metal gate (RMG) stacks according to one or more embodiments;

FIG. 1H illustrates a side cross sectional view of a replacement metal gate (RMG) stack of FIG. 1G;

FIG. 1I illustrates a bi-cross sectional view of the FinFET device of FIG. 1G after a capping layer has been disposed over the replacement metal gate (RMG) stacks according to one or more embodiments;

FIG. 1J illustrates a side cross sectional view of a replacement metal gate (RMG) stack of FIG. 1I;

FIG. 2 illustrates a schematic of capacitance components of a fin/gate structure;

FIG. 3 is a graph and schematic illustration showing the impact on effective capacitance (C_{eff}) when the replacement metal gate (RMG) stacks are recessed to different levels according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±13%, ±12%, ±11%, ±10%, ±9%, ±8%, ±7%, ±6%, ±5%, ±4%, ±3%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon. A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Epitaxy” is a process by which a deposited film is forced into a high degree of crystallographic alignment with the substrate. Epitaxial growth is broadly defined as the condensation of gas precursors to form a film on a substrate. Liquid precursors may also be used. Vapor precursors may be obtained by chemical vapor deposition (CVD) and laser ablation. Several epitaxy techniques are now available, such as molecular beam epitaxy (MBE), epitaxial CVD, or atomic layer epitaxy (ALE).

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Field effect transistors are voltage-controlled devices where its current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated IS and current entering the channel at the drain (D) is designated ID. Drain-to-source voltage is designated VDS. By applying voltage to gate (G), the current entering the channel at the drain (i.e., ID) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both are of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET, is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. sLogic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

As used herein, the term “K-value”, also known as dielectric constant, is an expression of the extent to which a material concentrates electric flux. In electronics, “K-value” refers to the capacitance of a material relative to silicon dioxide. A “high K-value” or “high-k” dielectric generally refers to a material having a higher dielectric constant as compared to silicon dioxide, and is typically greater than about 3.9, and may be greater than about 7.0. A “low K-value” or “low-K” dielectric generally refers to a material having a lower dielectric constant as compared to silicon dioxide, and is typically less than about 3.9, and may be less than about 3.

As semiconductor device size continues to shrink, increased design complexity has been necessary to maintain device performance. FinFET structures provide improvements in short channel performance over prior planar structures, but parasitic capacitance from gate-to-source/drain capacitance and gate-to-source/drain contact capacitance has become increasingly problematic with decreased device size. Generally, the effective capacitance (C_{eff}) within a FinFET is dominated between a gate and contact region. Parasitic capacitance reduces device performance, and can occur when parallel conductive lines are separated by a dielectric material. For example, in a transistor structures, the source and drain may be connected to a vertical conductive material (e.g. a conductive wire), and the gate may be connected with a vertical conductive material (e.g., a conductive wire) as well. These conductive materials may be two metal wires that are running parallel to one another and are separated by a dielectric material, such as an oxide. This structure may cause a parasitic capacitance across the dielectric, which may slow device performance and increase power consumption.

Parasitic capacitance depends on the dielectric constant of intervening materials as well as the spacing between the parallel conductive material structures (e.g., conductive wires). As device features shrink in size, less and less dielectric is positioned between the conductive structures, which may increase parasitic capacitance. While the use of low-K materials is desirable for reducing parasitic capacitance, low-K materials suffer from undesirable leakage as they are made thinner. For this reason, high-k materials have been used and are typically incorporated into replacement metal gate (RMG) structures in an effort to enable further size reduction without increasing undesirable leakage, but at the cost of increased parasitic capacitance.

According to one or more embodiments, semiconductor devices and methods of fabrication are provided in which device performance, particularly effective capacitance (C_{eff}), is improved by reducing the effective dielectric constant of one or more material layers forming the semiconductor device. Common dielectric materials include silicon dioxide, which has a dielectric constant of about 3.9. This dielectric constant may not adequately overcome more closely spaced parallel conductive lines. Air is characterized by a dielectric constant of about 1.

According to one or more embodiments, a semiconductor device and method of fabrication are provided in which parasitic capacitance is reduced by reducing the effective dielectric constant of one or more material layers of the replacement metal gate (RMG) structure between the source and drain regions. According to one or more embodiments, an airgap is disposed in or along the RMG stack to reduce parasitic capacitance and, thus, improve C_{eff}. According to one or more embodiments, one or more RMG stacks within a FinFET structure includes a high-K dielectric layer disposed along an outer lateral sides of the RMG stack, and the high K-dielectric layer is selectively etched to form one or more airgaps within the RMG stack, thus decreasing the effective dielectric constant of the high-k layer.

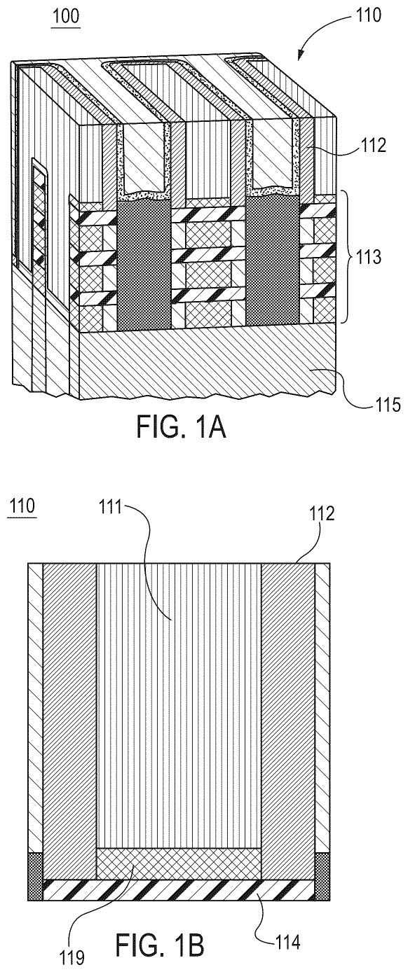

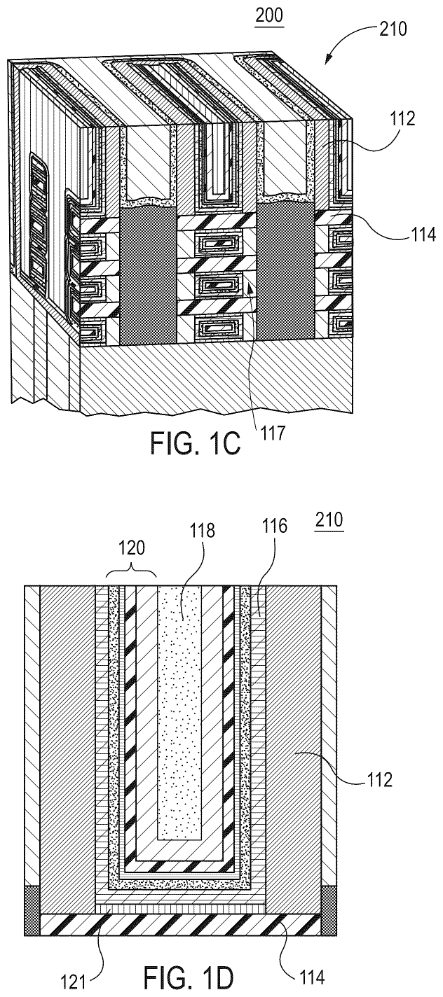

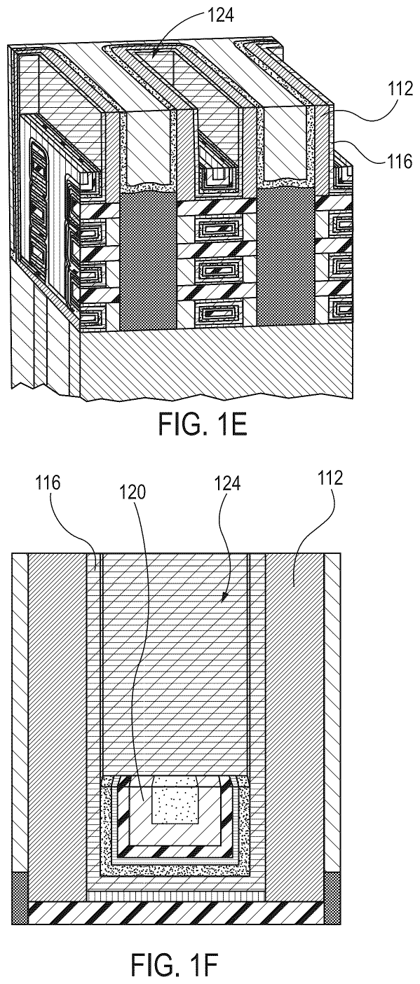

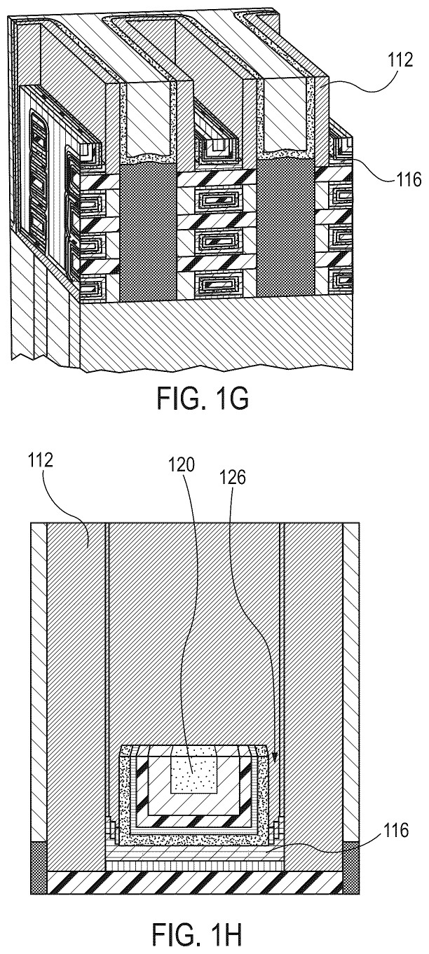

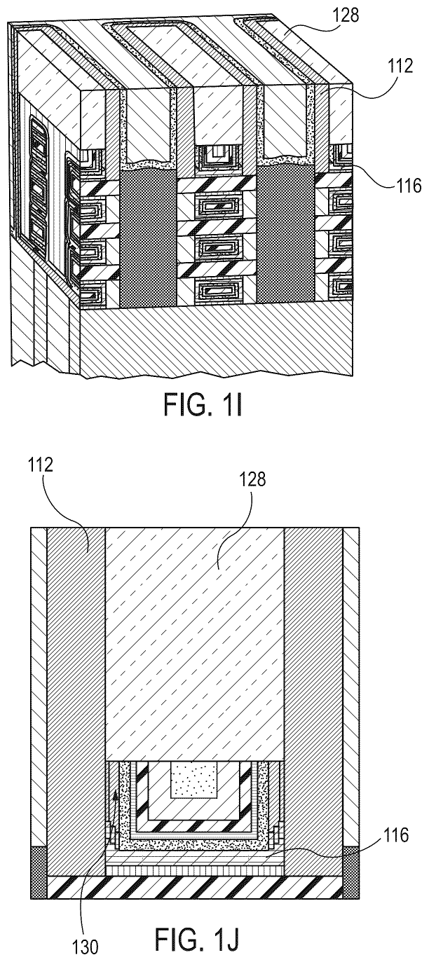

FIGS. 1A-1J are a bi-cross sectional views of various stages of forming a FinFET device according to one or more embodiments. As shown in FIG. 1A, an initial FinFET structure 100 is fabricated with dummy gate structures 110 formed across a top surface of a semiconductor stack 113 which is provided on a substrate 115. Any conventional methods and materials can be used in forming the semiconductor stack 113 and dummy gate structures 110. Further, while FIG. 1A depicts a view in which three dummy gate structures 110 are formed on top of a semiconductor stack 113 having three fin structures 117, this is only an example. Embodiments can be provided with any number of dummy gate 110 and fin structures 117. Further while the semiconductor stack 113 is depicted as having a certain number of layers disposed directly on a substrate 115 surface, any number of layers can be provided and can be disposed on a substrate 115 surface via one or more intermediate layers (not shown).

As more clearly shown in FIG. 1B, the dummy gate structure 110 is generally formed on a top layer 114 (e.g., silicon layer) of the semiconductor stack 113/fin structures 117 and generally comprises polysilicon material 111. While described herein as a polysilicon material, other suitable materials can alternatively be used in forming the dummy gate structure 110. Spacers 112 extend along the outer lateral sides of the polysilicon material 111. The spacers 112 are formed of dielectric material, and may be formed of high-k dielectric materials like HfO₂ and Si₃N₄ or low k dielectric materials like SiOCN, SiOC, and SiO₂. According to one or more embodiments, an oxide layer 119 is further disposed between the top layer 114 and the polysilicon material 111. The oxide layer 119 can be fabricated of any suitable oxide materials.

As shown in FIG. 1C, the FinFET structure 200 is shown after replacement of the dummy gate structures 110 with the replacement metal gate (RMG) structures 210 according to one or more embodiments. FIG. 1D shows an enlarged view of an RMG structure 210. It is noted that while a certain number of layers and types of materials are shown and described in forming the RMG structure 210, this is not intended to be limiting. Additional layers can be added and/or one or more of the described layers can be eliminated in accordance with known RMG structure 210 fabrication and design. As shown, according to one or more embodiments, the polysilicon material 111 forming the dummy gate structure 110 is removed by etching or other suitable removal process, leaving a recess between the spacers 112. The oxide layer 119 is also removed as shown in FIG. 1D, or in some embodiments the oxide layer 119 may remain. In the embodiment shown in FIGS. 1C-1D, after removal of the oxide layer 119, a gate oxide layer 121 is deposited on the top layer 114 (e.g., silicon layer) of the semiconductor stack 113/fin structures 117. According to one or more embodiments, the gate oxide layer 121 comprises one or more of silicon dioxide (SiO₂), silicon oxy nitride (SiON), silicon oxy carbon nitride (SiOCN), and silicon oxy carbide (SiOC). A high-k dielectric layer 116 is deposited over the gate oxide layer 121 and extends along inner lateral (as depicted in the view shown by FIG. 1D) surfaces of the spacers 112. According to one or more embodiments, the high-k dielectric layer 116 has a dielectric constant greater than about 10. In some embodiments, the high-k dielectric layer 116 comprises a metal oxide and can include one or more of hafnium oxide, zirconium oxide, aluminum oxide, their nitrides, and combinations thereof. According to one or more embodiments, one or more work function metals (WFM) 120 are layered in the RMG structure 210. The work function metals 120 can beneficially be incorporated to tune threshold voltage (Vₜ) and can comprise, for example, one or more of TiN, TiAlC, and TaN. A gate metal fill 118 is then deposited to form the RMG structure 210 within the recess left by the dummy gate polysilicon material 111.

According to embodiments, after formation the RMG structure 210 undergoes chemical mechanical planarization (CMP) and is recessed to form a vertical cavities 124, for example as shown in FIGS. 1E-1F. According to one or more embodiments, during CMP and recessing of the RMG structure 210, the high-k dielectric layer 116 remains in place extending along inner lateral (as best seen in the view shown by FIG. 1F) surfaces of the spacers 112.

According to one or more embodiments, the high-k dielectric layer 116 is selectively removed to expose the inner surfaces of the spacers 112 and to form openings 126 between the recessed RMG structure 210 and the spacers 112. The resulting structure is illustrated in FIGS. 1G-1H. According to embodiments, removal of the high-k dielectric layer 116 can be controlled to a desired depth based on device specifications and needs.

As shown in FIGS, 1A-1J, gate cap material 128 is deposited within the vertical cavities 124 to the surface of the recessed RMG structure 210 without entering the openings 126 to pinch off or block the openings 126 and form airgaps 130. By forming airgaps 130 in a recessed region of the high-k dielectric layer 116, the C_{eff} of the semiconductor device is improved by incorporating air (which has a dielectric constant of 1) into the removed portion of the layer of high-K dielectric material, thereby reducing the effective dielectric constant.

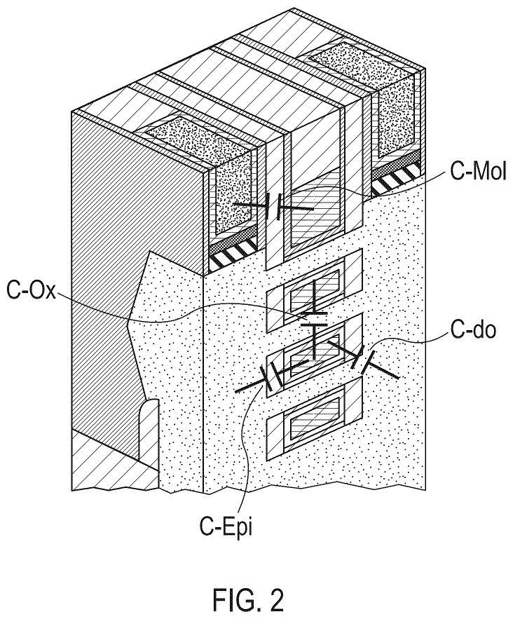

FIG. 2 shows an illustration of a fin/gate structure in which various capacitance components are labeled. The C-mol relates to capacitance due to the spacer 112 structure, and the contact to source/drain of the transistor. This component can generally be improved by using lower-K dielectric materials and thicker spacers. C-do relates to capacitance due to direct overlap of gate to substrate, and can generally be improved by using lower-K dielectric materials and thicker spacers. C-epi relates to capacitance due to gate-EPI, and can generally be improved by using lower-K dielectric materials and thicker spacers. C-Ox is capacitance due to the channel-gate dielectric, and can generally be improved by reducing the effective oxide thickness (EOT). By specific design, these capacitance components can be improved to have a positive impact on C_{eff}.

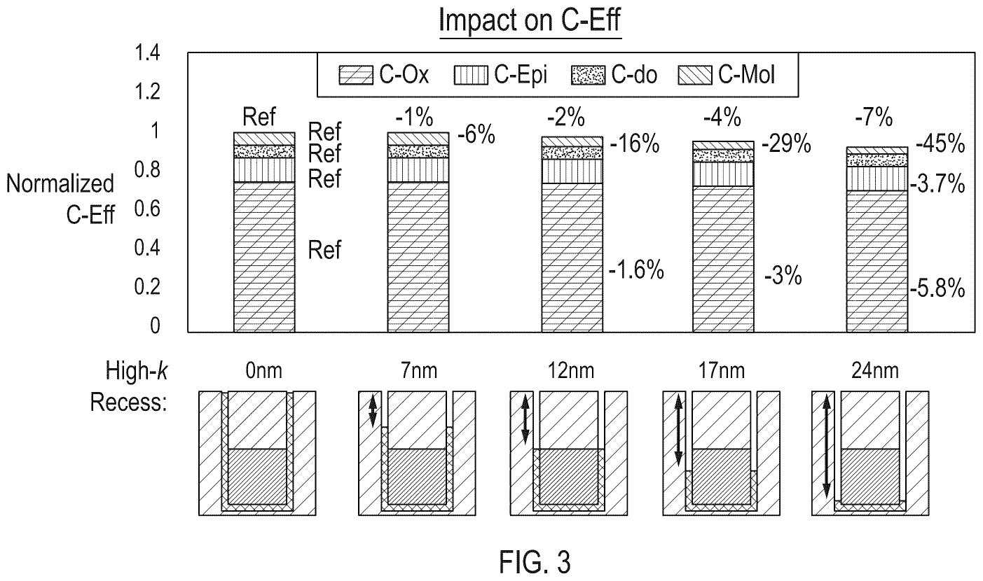

According to one or more embodiments, at least a portion of the high-k dielectric layer 116 is removed and pinched of closed off to form an airgap 130. FIG. 3 graphically illustrates the impact of the various capacitance components on C_{eff} when the high-k dielectric layer 116 is recessed to different levels and replaced with an airgap according to one or more embodiments. The first reference “Ref” bar depicts the C_{eff} and individual capacitance components for a structure in which the high-k dielectric layer 116 has not been removed, and no airgaps 130 are provided. The exemplary reference structure “Ref” shows a total height of 25 nm of high-k dielectric layer 116 extending from a bottom of the gate to the top, with 0 nm removed. Next, 7 nm of the high-k dielectric layer 116 has been removed, resulting in a 1% decrease in the impact on C_{eff}. Removal of 12 nm of the high-k dielectric layer 116 results in a 2% decrease in the impact on C_{eff}. Removal of 17 nm of the high-k dielectric layer 116 results in a 4% decrease in the impact on C_{eff}. Removal of 24 nm of the high-k dielectric layer 116 resulting in a 7% decrease in the impact on C_{eff}. As demonstrated, the benefit of high-K dielectric layer 116 removal becomes significant once the depth of removal reaches the recessed RMG structure 210 (e.g., 17 nm and 24 nm removal). As further demonstrated, C-Ox provides the greatest impact on C_{eff} followed by C-Epi, C-do, and C-Mol.

The effective capacitance (C_{eff}) within a chip is dominated between gate and contact region. Embodiments are provided in which a high-k dielectric layer disposed on a RMG sidewall is recessed and pinched or closed off to form an airgap. The present methods provide a simplified one step process which effectively simplifies device fabrication flow and minimizes reduction in C_{eff}. The device structures are further compatible with existing downstream processes. By forming airgaps within the RMG region, capacitance reduction can be maximized between gate-contact (C-Mol), channel-gate dielectric (C-Ox) and gate-EPI (C-Epi) components of overall effective capacitance (C_{eff}).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

What is claimed is:

1. A semiconductor structure comprising:
a semiconductor stack disposed on a substrate;
a metal gate structure disposed on a top surface of the semiconductor stack, the metal gate structure having a bottom surface, a top surface, and lateral side surfaces;
a high-k dielectric layer disposed between the bottom surface of the metal gate structure and the top surface of the semiconductor stack, and on a bottom portion of the lateral side surfaces of the metal gate structure;
a spacer layer extending along the lateral side surfaces of the metal gate structure, wherein the spacer layer is separated from the lateral side surfaces of the metal gate structure by (a) the high-k dielectric layer disposed between the spacer layer and metal gate structure on the bottom portion of the lateral side surfaces of the metal gate structure, and (b) an airgap disposed between the spacer layer and metal gate structure above the bottom portion of the lateral side surfaces of the metal gate structure, the airgap providing a reduced effective dielectric constant between the lateral side surfaces of the metal gate structure and the spacer layer; and
a gate cap material disposed on the top surface of the metal gate structure, the gate cap material extending above but not into the airgap.

2. The semiconductor structure of claim 1, wherein the high-k dielectric layer has a dielectric constant greater than about 10.

3. The semiconductor structure of claim 1, wherein the high-k dielectric layer comprises a metal oxide.

4. The semiconductor structure of claim 3, wherein the high-k dielectric layer comprises one or more of hafnium oxide, zirconium oxide, aluminum oxide, and their nitrides.

5. The semiconductor structure of claim 1, wherein the spacers comprise a dielectric material.

6. The semiconductor structure of claim 5, wherein the spacers comprise a high-k dielectric material.

7. The semiconductor structure of claim 6, wherein the spacers comprise one or more of HfO₂ and Si₃N₄.

8. The semiconductor structure of claim 5, wherein the spacers comprise a low-K dielectric material.

9. The semiconductor structure of claim 8, wherein the spacers comprise one or more of SiOCN, SiOC, and SiO₂.

10. A replacement metal gate structure for a semiconductor device comprising:
a gate metal fill;
at least one work function metal layers surrounding a bottom surface and lateral side surfaces of the gate metal fill;
a high-k dielectric layer surrounding a bottom surface and a bottom portion of the lateral side surfaces of the gate metal fill, the at least one work function layer disposed between the high-k dielectric layer and the gate metal fill;
a spacer layer extending along the lateral side surfaces of the gate metal fill, the high-k dielectric layer disposed between the spacer layer and the at least one work function layer at the bottom portion of the lateral side surfaces of the gate metal fill, and an airgap disposed between the spacer layer and the at least one work function layer above the high-k dielectric layer; and
a gate cap material disposed between the spacer layer and extending along a top surface of the metal gate fill and above the airgap.

11. The replacement metal gate structure of claim 10, wherein the high-k dielectric layer has a dielectric constant greater than about 10.

12. The replacement metal gate structure of claim 10, wherein the high-k dielectric layer comprises a metal oxide.

13. The replacement metal gate structure of claim 12, wherein the high-k dielectric layer comprises one or more of hafnium oxide, zirconium oxide, aluminum oxide, and their nitrides.

14. The replacement metal gate structure of claim 10, wherein the spacers comprise a dielectric material.

15. The replacement metal gate structure of claim 14, wherein the spacers comprise a high-k dielectric material.

16. The replacement metal gate structure of claim 15, wherein the spacers comprise one or more of HfO₂ and Si₃N₄.

17. The replacement metal gate structure of claim 14, wherein the spacers comprise a low-K dielectric material.

18. The replacement metal gate structure of claim 17, wherein the spacers comprise one or more of SiOCN, SiOC, and SiO₂.

19. A method of forming a semiconductor structure, the method comprising:
providing a semiconductor stack on a substrate surface with a gate structure on a top surface of the semiconductor stack, a spacer structure extending along outer lateral sides of the gate structure, and a high-k dielectric layer disposed between the spacer structure and the gate structure;
selectively removing at least a portion of the high-k dielectric layer to provide an opening between the spacer structure and the gate structure; and
depositing a gate cap material on a top surface of the gate structure to block the opening and to form an airgap between the spacer structure and the gate structure, the airgap providing a reduced effective dielectric constant in the high-k dielectric layer and improves an effective capacitance of the semiconductor structure.

20. The method according to claim 19,
wherein the at least a portion of the high-k dielectric layer is between the top surface of the gate structure to a depth along the outer lateral sides of the gate structure, and wherein the gate cap material extends along the top surface of the gate cap structure and over the opening.
